(19) United States
(12) Patent Application Publication
(10) Pub. No.: US 2008/0032652 A1
(43) Pub. Date: Feb. 7, 2008

(54) Phase detection apparatus and method, phase locked loop circuit and control method thereof, and signal reproducing apparatus and method

(75) Inventors: Hul Zhao, Suwon-si (KR); Hyun-soo Park, Seoul (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/710,426

(22) Filed: Feb. 26, 2007

(30) Foreign Application Priority Data
Aug. 4, 2006 (KR) 2006-73821

(51) Int. Cl. H04B 17/00; H03M 1/00

(52) U.S. Cl. 455/226.4; 341/142

(57) ABSTRACT

A phase detection apparatus and method, a PLL circuit and a control method thereof, and a signal reproducing apparatus and method which can provide anti-noise and anti-ISI characteristics while reducing the scale of hardware used in an optical disc reproducing system having high-ISI conditions include a pulse forming unit to detect binary data of an input signal, an ideal input signal generating unit to generate an ideal input signal based on the detected binary data, and a phase error signal generating unit to generate a phase error signal based on the input signal and the ideal input signal.

### CROSS-REFERENCE TO RELATED APPLICATION

This application claims the benefit of Korean Application No. 2006-73821, filed Aug. 4, 2006, in the Korean Intellectual Property Office, the disclosure of which is incorporated herein by reference.

### BACKGROUND OF THE INVENTION

1. Field of the Invention

Aspects of the present invention relate to phase detection and phase locked loops (PLLs), and more particularly, to a phase detection apparatus and method, a PLL circuit and a control method thereof, and a signal reproducing apparatus and method that are suitable for an optical disc reproducing system.

2. Description of the Related Art

Optical disc reproducing systems reproduce data recorded on optical discs such as compact discs (CDs), digital versatile discs (DVDs), blue-ray discs (BDs), and high-definition DVDs (HD-DVDs). In particular, optical disc reproducing systems that reproduce data recorded on BDs or HD-DVDs can be called “HD optical disc reproducing systems.”

In order to reproduce a radio frequency (RF) signal read from an optical disc, optical disc reproducing systems require a sampling clock (or a bit clock) which is synchronized with the RF signal. In optical disc reproducing systems, the sampling clock is generated by a PLL circuit. Specifically, the PLL circuit is used to generate a sampling clock synchronized with the RF signal. In general, PLL circuits use a zero-crossing point as the phase of an RF signal, and detect a phase error between the RF signal and the zero-crossing point based on a sampling point adjacent to the zero-crossing point.

However, the waveform of an RF signal reproduced by an HD optical disc reproducing system is seriously affected by inter-symbol interference (ISI). The reason why the waveform is seriously affected by ISI is that the HD optical disc reproducing system has a spot size greater than a pit length. If a reproduced RF signal is affected by ISI, it may be impossible to detect a zero-crossing point of the reproduced RF signal. When a reproduced RF signal is affected by ISI to the extent that its zero-crossing point cannot be detected, this condition is called a “high ISI condition.” The channel characteristics of an RF signal reproduced under a high ISI condition are sensitive to even low levels of noise, thus leading to a malfunction of the optical disc reproducing system.

Accordingly, there is a strong possibility that the zero-crossing point of an RF signal reproduced under a high ISI condition may not be detectable. When the zero-crossing point of a reproduced RF signal is not detected, the phase locking of the reproduced RF signal may fail. When the phase locking of a reproduced RF signal fails, it is impossible for the optical disc reproduction system to perform signal reproduction in a stable fashion.

FIG. 1 is a block diagram of a conventional PLL circuit 100 that has been proposed in order to solve the above problems. Referring to FIG. 1, the conventional PLL circuit 100 includes an analog-to-digital converter (ADC) 101, delayers 102 and 103, a pattern string detector 104, a phase error generating unit 105, a low pass filter (LPF) 106, a digital-to-analog converter (DAC) 107, a voltage-controlled oscillator (VCO) 108, a Viterbi decoder 109, and a reference level learning circuit 110.

The ADC 101 samples an input analog radio-frequency (RF) signal using the output of the VCO 108 as a sampling clock. The sampled RF signal from the ADC 101 is respectively delayed by one PLL clock at each of the delayers 102 and 103. Accordingly, three consecutive RF signals are input to the pattern string detector 104.

The pattern string detector 104 compares the three consecutive RF signals with all possible ideal pattern strings in order to detect an ideal RF pattern string that has a minimum Euclidean distance with respect to the three consecutive RF signals. The pattern string detector 104 then outputs the ideal RF pattern identification (ID) information of the detected ideal RF pattern string to the phase error generating unit 105. Using the output signal of the delayer 102, the phase error generating unit 105 generates phase error information based on the ideal RF pattern ID information. The output signal of the delayer 102 corresponds to a value of the central sample of an RF pattern. Therefore, the phase error generating unit 105 subtracts a central sample value of an ideal RF pattern from the central sample value of the RF pattern in order to generate the phase error information.

The phase error information is transmitted to the LPF 106. The output of the LPF 106 is transmitted to the DAC 107. The DAC 107 outputs a voltage signal to drive the VCO 108. The VCO 108 outputs an oscillating signal that is used as the sampling clock by the ADC 101.

The Viterbi decoder 109 and the reference level learning circuit 110 are included to adapt to changes in channel characteristics. The Viterbi decoder 109 uses a reference level transmitted from the reference level learning circuit 110 to detect binary data of the sampled RF signal. The reference level learning circuit 110 monitors the input and output of the Viterbi decoder 109 to adaptively correct a reference level. The corrected reference level is transmitted to the Viterbi decoder 109 and the pattern string detector 104.

Accordingly, the conventional PLL circuit 100 can correct the nonlinearity of reproduced RF signals. Therefore, the conventional PLL circuit 100 is not susceptible to channel characteristics even under high-ISI conditions, and thus can provide stable signal reproduction.

However, as the recording density of optical discs increases, the conventional PLL circuit 100 must be designed to provide a wider detection window so that the pattern string detector 104 can compare a large number of input RF signal pattern strings. An increase in the width of the detection window leads to an increase in the scale of hardware used to implement the conventional PLL circuit 100. This increase in the scale, or size, of the hardware needed to design a PLL circuit which is compatible with modern high density optical discs can cost more money to implement than the conventional PLL circuit 100 and can complicate the manufacturing process of the conventional PLL circuit 100.

### SUMMARY OF THE INVENTION

Aspects of the present invention provide a phase detection apparatus and method, a phase locked loop circuit and a control method thereof, and a signal reproducing apparatus and method, the use of which can provide anti-noise and anti-ISI characteristics while reducing the scale of hardware used in an optical disc reproducing system having high-ISI conditions.

Additional aspects and/or advantages of the invention will be set forth in part in the description which follows and, in part, will be obvious from the description, or may be learned by practice of the invention.

According to an aspect of the present invention, an apparatus for detecting the phase of an input signal includes a pulse forming unit to detect and output binary data of the input signal, an ideal input signal generating unit to generate an ideal input signal based on the detected binary data, and a phase error signal generating unit to generate a phase error signal based on the input signal and the ideal input signal.

The apparatus may further include a reference level generating unit which compares the input signal with the binary data output by the pulse forming unit in order to generate a reference level adaptive to a channel change.

The reference level generating unit may transmit the generated reference level to the pulse forming unit, and the pulse forming unit may detect the binary data based on the generated reference level.

The apparatus may further include a first delay unit to delay the input signal during the operations of the pulse forming unit and the ideal input signal generating unit and to transmit the delayed input signal as the input signal used by the phase error signal generating unit to generate the phase error signal, and a second delay unit to delay the input signal during the operation of the pulse forming unit and to transmit the delayed input signal as the input signal which the reference level generating unit compares to the output signal of the pulse forming unit.

The phase error signal generating unit may include a first difference detector to detect and output a difference between the input signal and the ideal input signal a second difference detector to detect a plurality of differences between a plurality of other ideal input signals using N consecutive ideal input signal samples output from the ideal input signal generating unit, and a phase error calculator to calculate a phase error based on the difference detected by the first difference detector and the plurality of differences detected by the second difference detector in order to generate the phase error signal, wherein the difference detected by the first difference detector is a phase error.

The phase error signal generating unit may further include a first delayer to delay the difference output by the first difference detector. The second difference detector may include a second delayer to delay the ideal input signal sample, a detector to detect and to output a difference between the ideal input signal sample and the output signal of the second delayer as one of the plurality of differences, and a third delayer to delay the difference output by the detector and to output the delayed difference as another one of the plurality of differences.

The second difference detector may further include a quantization unit to quantize the difference output by the detector and to output the quantized difference to the third delayer and the phase error calculator as one of the plurality of differences.

The second difference detector may further include a dead zone code unit to convert the output signal of the detector into a dead zone code and to output the dead zone code to the third delayer and the phase error calculator as one of the plurality of differences.

According to another aspect of the present invention a method of detecting the phase of an input signal includes detecting binary data of the input signal, generating an ideal input signal based on the detected binary data, and generating a phase error signal based on the binary data and the ideal input signal.

The generating of the phase error signal may include detecting a difference between the input signal and the ideal input signal, detecting a plurality of differences between a plurality of other ideal input signals using N consecutive ideal input signal samples, and calculating a phase error based on the detected difference and the detected plurality of differences to generate the phase error signal.

The detecting of the plurality of differences between the ideal input signals may include quantizing one of the plurality of differences and detecting the plurality of differences used to generate the phase error signal based on the quantization results.

The detecting of the plurality of differences between the ideal input signals may include converting one of the plurality of differences into a dead zone code and detecting a plurality of differences used to generate the phase error signal based on the results of the conversion into the dead zone code.

The method may further include generating a reference level adaptive to a channel change based on the input signal and the detected binary data, wherein the ideal input signal may be generated based on the generated reference level.

According to another aspect of the present invention, a phase-locked loop (PLL) circuit includes an analog-to-digital converter (ADC) to convert an input signal into a digital signal and output the digital signal, a phase detector to detect a phase error signal of the digital signal output by the ADC, a low-pass filter (LPF) to low-pass filter the detected phase error signal, a digital-to-analog converter (DAC) to convert the low-pass filtered signal of the LPF into a second digital signal, and a voltage controller oscillator (VCO) to generate a clock signal of the PLL using the second digital signal converted by the DAC, wherein the phase detector detects the phase error signal based on the digital signal output by the ADC and an ideal signal corresponding to the digital signal output by the ADC.

According to another aspect of the present invention a phase-locked loop (PLL) circuit includes an analog-to-digital converter (ADC) to convert an input signal into a digital signal and output the digital signal, an interpolator to interpolate the digital signal output by the ADC, a phase detector to detect a phase error signal of the interpolated signal, a low-pass filter (LPF) to low-pass filter the detected phase error signal, and an interpolation parameter calculator to calculate an interpolation parameter based on the low-pass filtered signal and to transmit the calculated interpolated parameter to the interpolator.

According to another aspect of the present invention, a method of controlling a phase-locked loop (PLL) which receives an input signal includes generating a phase error signal using the input signal and an ideal input signal corresponding to the input signal, low-pass filtering the phase error signal, converting the low-pass filtered signal into a digital signal, and generating a clock signal of the PLL using the digital signal.

According to another aspect of the present invention, a method of controlling a phase-locked loop (PLL) of an input signal includes interpolating the input signal, generating a phase error signal using the interpolated signal and an ideal input signal corresponding to the interpolated signal, low-pass filtering the phase error signal, calculating an interpolation parameter using the low-pass filtered signal, and using the interpolation parameter for the interpolating of the input signal.

According to another aspect of the present invention, a signal reproducing apparatus with a function of detecting the phase of an RF signal read from a disc includes a pulse forming unit to detect binary data of the RF signal, an ideal input signal generating unit to generate an ideal input signal based on the detected binary data, and a phase error signal generating unit to generate a phase error signal based on the input signal and the output signal of the ideal input signal generating unit, wherein the binary data is a reproduction signal.

According to another aspect of the present invention, a signal reproducing apparatus with a function of controlling a phase-locked loop (PLL) which receives a radio frequency (RF) signal read from a disc includes an analog-to-digital converter (ADC) to convert the RF signal into a digital signal and output the digital signal, a phase detector to detect a phase error signal for the digital signal output by the ADC, a low-pass filter (LPF) to low-pass filter the detected phase error signal, a digital-to-analog converter (DAC) to convert the low-pass filtered signal into a second digital signal, and a voltage-controlled oscillator (VCO) to generate a clock signal of the PLL using the second digital signal converted by the DAC, wherein the phase detector detects the phase error signal based on the digital signal output by the ADC and an ideal signal corresponding thereto and outputs binary data of the RF signal.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a conventional PLL circuit;

FIG. 2 is a block diagram of a phase detection apparatus according to an embodiment of the present invention;

FIG. 3 is a block diagram of the phase error signal generating unit 204 illustrated in FIG. 2 according to an embodiment of the present invention;

FIGS. 4A, 4B, 4C, 4D, 4E, 4F, 4G, 4H, 4I, and 4J are diagrams illustrating the operating principle of a phase error calculator 306 illustrated in FIG. 3;

FIG. 5 is a block diagram of another embodiment of the phase error signal generating unit 204 illustrated in FIG. 2;

FIG. 6 is a graph illustrating the relationship between the input and output signals of the quantizer 505 illustrated in FIG. 5;

FIG. 7 is a block diagram of still another embodiment of the phase error signal generating unit 204 illustrated in FIG. 2;

FIG. 8 is a graph illustrating the relationship between the input and output signals of the dead zone code unit 705 illustrated in FIG. 7;

FIG. 9 illustrates an example of a truth table contained in the phase error calculator 707 illustrated in FIG. 7;

FIG. 10 is a block diagram of a phase detection apparatus according to another embodiment of the present invention;

FIG. 11 is a block diagram of a phase detection apparatus according to still another embodiment of the present invention;

FIG. 12 is a diagram illustrating the way in which two types of binary data are output from the double-output Viterbi decoder 1101 illustrated in FIG. 11;

FIG. 13 is a flowchart illustrating a phase detecting method according to an embodiment of the present invention;

FIG. 14 is a flowchart illustrating an example of the phase error signal generating operation 1303 illustrated in FIG. 13;

FIG. 15 is a flowchart illustrating another example of the phase error signal generating operation 1303 illustrated in FIG. 13;

FIG. 16 is a flowchart illustrating a phase detecting method according to another embodiment of the present invention;

FIG. 17 is a block diagram of a PLL circuit according to an embodiment of the present invention;

FIG. 18 is a block diagram of a PLL circuit according to another embodiment of the present invention;

FIG. 19 is a block diagram of a PLL circuit according to another embodiment of the present invention;

FIG. 20 is a block diagram of a PLL circuit according to another embodiment of the present invention;

FIG. 21 is a flowchart illustrating a PLL controlling method according to an embodiment of the present invention;

FIG. 22 is a flowchart illustrating a PLL controlling method according to another embodiment of the present invention;

FIG. 23 is a flowchart illustrating a PLL controlling method according to still another embodiment of the present invention; and

FIG. 24 is a flowchart illustrating a PLL controlling method according to another embodiment of the present invention.

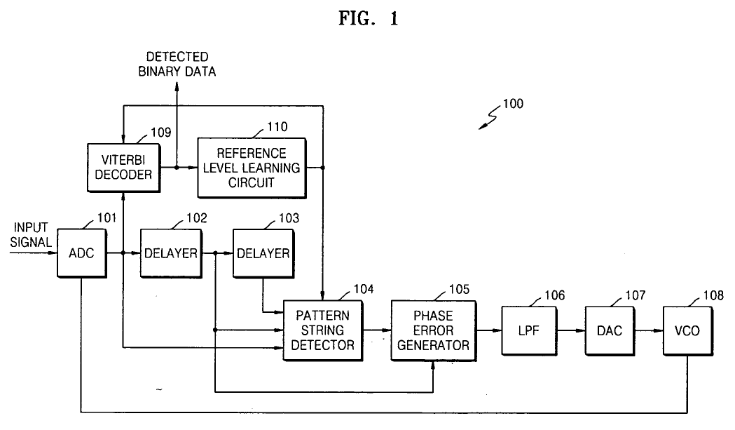

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

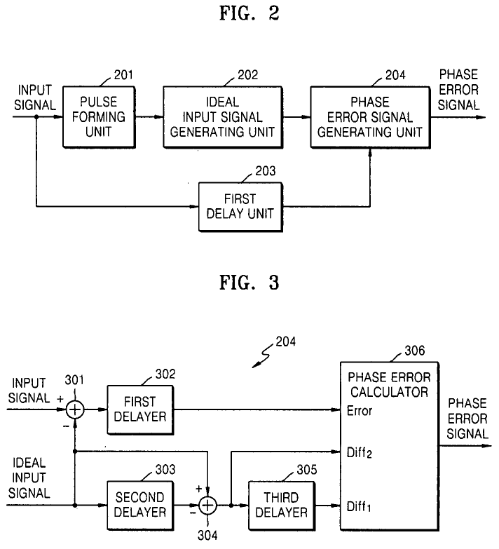

FIG. 2 is a block diagram of a phase detection apparatus according to an embodiment of the present invention. Referring to FIG. 2, the phase detection apparatus includes a pulse forming unit 201, an ideal input signal generating unit 202, a first delay unit 203, and a phase error signal generating unit 204.

The pulse forming unit 201 detects binary data of an input signal. The binary data may have the format of a non-return to zero (NRZ) code, although it is understood that the binary data may also have other formats. To this end, the pulse forming unit 201 may, for example, be implemented using one of a slicer, an equalizer followed by a slicer, a finite delay tree search (FDTS) detector, or a Viterbi decoder. The binary data from the pulse forming unit 201 may be used as a reproduction signal. Accordingly, when the phase detection apparatus illustrated in FIG. 2 is used with an optical disc reproducing system, it is unnecessary to provide a separate component to detect a reproduction signal corresponding to binary data from an RF signal that is read from a disc (not illustrated). The input signal may be a digital RF signal, but it is understood that the input signal may also be other types of signals as well.

The ideal input signal generating unit 202 generates an ideal input signal based on the binary data transmitted from the pulse forming unit 201. The ideal input signal generating unit 202 may be a linear channel whose output is expressed by Equation (1).

$$PR ( {I}_{1} , {I}_{2} , {I}_{3} , … , {I}_{n} ) = {\sum }_{j = 1}^{n} {I}_{j} \cdot X ( k - j ) \qquad ( 1 )$$

Where PR denotes partial response, Iⱼ denotes a coefficient of the linear channel and X(k) denotes binary data with a value of 1 or −1 that is input at a point of time k.

Alternatively, the ideal input signal generating unit 202 may be an arbitrary channel with n being a length of a finite window whose output is expressed by Equation (2):

PRₙ=F(X(k),X(k−1),X(k−2), . . . ,X(k−n+1)) (2)

where F( . . . ) is the representation of PRₙ as a function of X(k), X(k−1), . . . , X(k−n+1). The arbitrary channel may be implemented using a memory structure.

The first delay unit 203 delays the input signal by amounts of time equal to the operating periods of the pulse forming unit 201 and the ideal input signal generating unit 202. Accordingly, the ideal input signal transmitted from the ideal input signal generating unit 202 corresponds to the output signal of the first delay unit 203. Based on the ideal input signal transmitted from the ideal input signal generating unit 202 and the delayed input signal transmitted from the first delay unit 203, the phase error signal generating unit 204 generates and outputs a phase error signal indicating a phase error of the input signal.

When the input signal is an RF signal, the ideal input signal from the ideal input signal generating unit 202 and the output signal from the first delay unit 203 are defined as an ideal RF signal and a delayed real RF signal, respectively. The input signal may be a digital signal.

As described above, the phase detection apparatus of FIG. 2 can be constructed to generate the phase error signal using the pulse forming unit 201, the ideal input signal generating unit 202, and the phase error signal generating unit 204.

FIG. 3 is a block diagram of the phase error signal generating unit 204 according to an embodiment of the present invention. Referring to FIG. 3, the phase error signal generating unit 204 includes a first subtractor 301, a first delayer 302, a second delayer 303, a second subtractor 304, a third delayer 305, and a phase error calculator 306.

The first subtractor 301 detects a difference between an input signal and an ideal input signal. The detected difference can be expressed as an error between the input signal and the ideal input signal. Accordingly, the first subtractor 301 can be defined as a difference detector that detects the difference between the input signal and the ideal input signal.

The input signal that is input to the first subtractor 301 can be defined as a real RF signal corresponding to a delayed input signal that is output from the first delay unit 203. The ideal input signal can be defined as an ideal RF signal corresponding to an ideal input signal that is input to the first subtractor 301. The ideal input signal is transmitted from the ideal input signal generating unit 202.

The first delayer 302 delays a signal (or an error) from the first subtractor 301. The delayed error from the first delayer 302 is input to an “Error” input port of the phase error calculator 306.

The second delayer 303 delays the ideal input signal by one clock signal. The second subtractor 304 subtracts the delayed input signal of the second delayer 303 from the ideal input signal. Accordingly, the first delayer 303 and the second subtractor 304 can be jointly defined as a differential operator that outputs a difference between ideal input signals. The output signal of the second subtractor 304 is input to a “Diff2” input port of the phase error calculator 306.

The third delayer 305 delays the output signal of the second subtractor 304. The output signal of the third delayer 305 is input to a “Diff1” input port of the phase error calculator 306.

The second delayer 303, the second subtractor 304 and the third delayer 305 can be jointly defined as a difference detector that detects a plurality of differences between ideal input signals using N consecutive ideal input signal samples. The second subtractor 304 can be defined as a detector that detects a difference between the output signal of the second delayer 303 and the ideal input signal sample and outputs the detected difference as one (Diff2) of the plurality of differences.

The phase error calculator 306 may be implemented using a truth table that is defined by Equation (3):

1) Case 1

Diff1>Threshold, Diff2>Threshold: phase error info=Error/(Diff1+Diff2)

2) Case 2

Diff1<-Threshold, Diff2<-Threshold: phase error info=Error/(Diff1+Diff2)

3) Case 3

Otherwise: phase error info=0 (3)

where the threshold is a non-negative constant value.

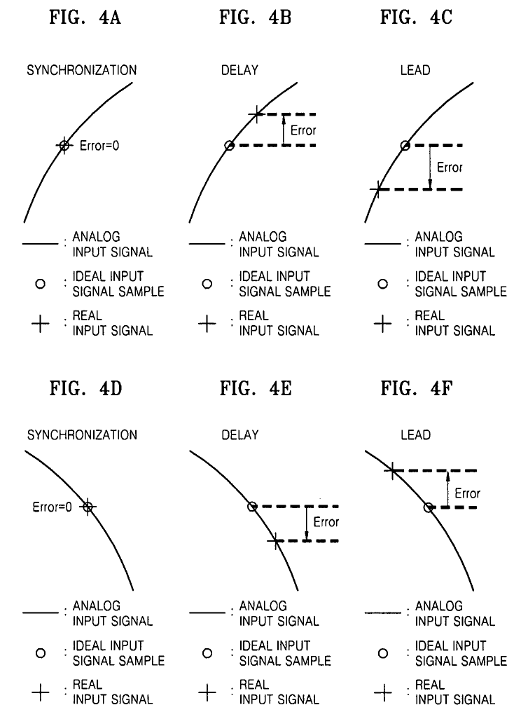

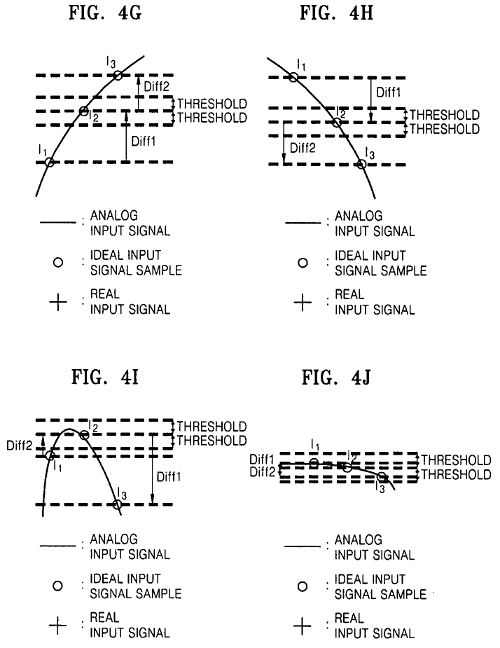

FIGS. 4A, 4B, 4C, 4D, 4E, 4F, 4G, 4H, 4I, and 4J are diagrams illustrating the operating principle of the phase error calculator 306 illustrated in FIG. 3. FIGS. 4A, 4B and 4C illustrate analog input signals (e.g., analog RF signals) with a rising edge, while FIGS. 4D, 4E, and 4F illustrate analog input signals (e.g., analog RF signals) with a falling edge.

If a real input signal is sampled according to a phase locked loop (PLL) clock signal without a phase error, a sampled input signal at the rising or falling edge is statistically identical to the ideal input signal as illustrated in FIGS. 4A and 4D. In this case, an expected error between the real input signal and the ideal input signal is “0.”

If a real input signal is sampled according to a PLL clock signal with a delayed phase error, the sampled input signal at the rising edge is statistically greater than the ideal input signal, as illustrated in FIG. 4B. In this case, an expected error between the real input signal and the ideal input signal has a positive value.

If a real input signal is sampled according to a PLL clock signal with a lead phase error, the sampled input signal at the rising edge is statistically smaller than the ideal input signal, as illustrated in FIG. 4C. In this case, an expected error between the real input signal and the ideal input signal has a negative value.

If a real input signal is sampled according to a PLL clock signal with a delayed phase error at the falling edge, the sampled input signal at the falling edge is statistically smaller than the ideal input signal, as illustrated in FIG. 4E. In this case, an expected error between the real input signal and the ideal input signal has a negative value.

If a real input signal is sampled according to a PLL clock signal with a lead phase error at the falling edge, the sampled input signal at the falling edge is statistically greater than the ideal input signal, as illustrated in FIG. 4F. In this case, an expected error between the real input signal and the ideal input signal has a positive value.

As can be seen from FIGS. 4A, 4B, 4C, 4D, 4E and 4F, an error between a real input signal and an ideal input signal is affected by a PLL clock phase error, an edge type, and an edge slope ratio, while the polarity of an expected error between the real input signal and the ideal input signal is affected only by the PLL clock phase error and the edge type. Therefore, the error between the real input signal and the ideal input signal can be used to compute the phase error depending on the edge type.

FIGS. 4G, 4H, 4I and 4J illustrate a scheme to determine the edge type that is used in the phase error calculator 306. Referring to FIG. 4G, three consecutive ideal input signal samples I₁, I₂ and I₃ are arranged in a rising edge of the signal. If an edge slope ratio is high (steep) enough, Diff1 and Diff2 are all greater than a preset threshold value of “0” or more. At this point, the “Error” input of the phase error calculator 306 is identical to an error between a real input signal and an ideal input signal I₂. This case corresponds to Case 1 of Equation (3). In this case, the result of Equation (3) exhibits a positive monotonic relationship of the phase error of a PLL clock signal.

Referring to FIG. 4H, three consecutive ideal input signal samples I₁, I₂ and I₃ are arranged in a falling edge of the signal. If an edge slope ratio is high (steep) enough, Diff1 and Diff2 are all smaller than a preset negative threshold having an absolute value of “0” or more. At this point, the “Error” input of the phase error calculator 306 is identical to an error between a real input signal and an ideal input signal I₂. This case corresponds to Case 2 of Equation (3). In this case, the result of Equation (3) exhibits a positive monotonic relationship of the phase error of a PLL clock signal.

Referring to FIG. 4I, three consecutive ideal input signal samples I₁, I₂ and I₃ do not increase or decrease as a rising or falling edge. In this case, it is virtually impossible to estimate a phase error. This case corresponds to Case 3 of Equation (3), where the phase error calculator 306 outputs a value of “0.”

In addition, if a threshold has a positive value (threshold>0) and the absolute value of an edge slope ratio is smaller than the threshold, the phase error calculator 306 can disregard edges of a signal. FIG. 4J illustrates a case where the absolute value of an edge slope ratio is smaller than the threshold even when three consecutive ideal input signal samples I₁, I₂ and I₃ decrease in a falling edge. This case corresponds to Case 3 of Equation (3), where the phase error calculator 306 outputs a value of “0.” Therefore, using a selected threshold, the phase error calculator 306 computes a phase error at an edge having a desirable slope ratio. The selection of an optimal threshold can enhance the performance of the phase error calculator 306.

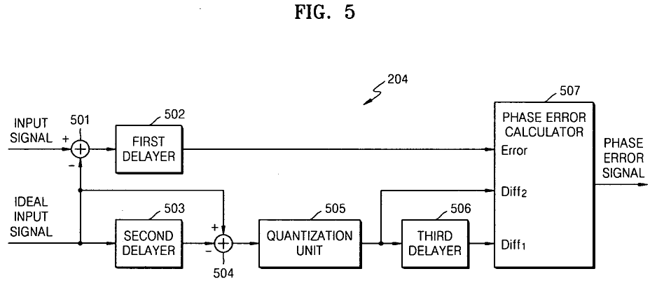

FIG. 5 is a block diagram of another embodiment of the phase error signal generating unit 204 shown in FIG. 2. The phase error signal generating unit 204 illustrated in FIG. 5 has an effect equivalent to the effect of adding a quantization unit 505 to the phase error signal generating unit 204 illustrated in FIG. 3. A first subtractor 501, a first delayer 502, a second delayer 503, a second subtractor 504, and a third delayer 506 illustrated in FIG. 5 are similar to the first subtractor 302, the first delayer 303, the second delayer 304, and the third delayer 305 illustrated in FIG. 3.

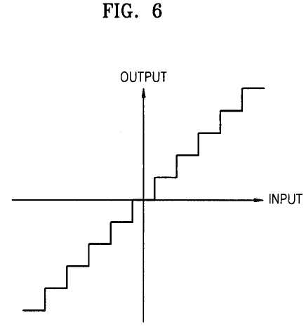

The quantization unit 505 quantizes the output signal of the second subtractor 504. The relationship between the input and output signals of the quantization unit 505 is illustrated in FIG. 6. The possible set of values output by the quantization unit 505 is preferably restricted to be smaller than the possible set of values input to the quantization unit 505. The addition of the quantization unit 505 reduces the scale of the phase error calculator 507. The quantization unit 505 transmits the output signal to the third delayer 506 and to the “Diff2” input port of the phase error calculator 507. Accordingly, the output signal of the quantization unit 505 can be defined as one of a plurality of differences between ideal input signals that are detected using N consecutive ideal input signal samples.

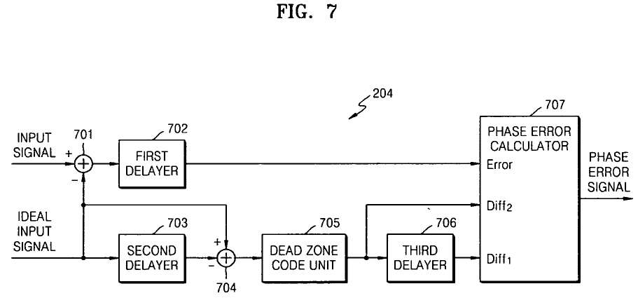

FIG. 7 is a block diagram of another embodiment of the phase error signal generating unit 204 shown in FIG. 2. The phase error signal generating unit 204 illustrated in FIG. 7 has an effect equivalent to the effect of adding a dead zone code unit 705 to the phase error signal generating unit 204 illustrated in FIG. 3. Therefore, a first subtractor 701, a first delayer 702, a second delayer 703, a second subtractor 704, and a third delayer 706 are similar to the first subtractor 301, the first delayer 302, the second delayer 303, the second subtractor 304, and the third delayer 305.

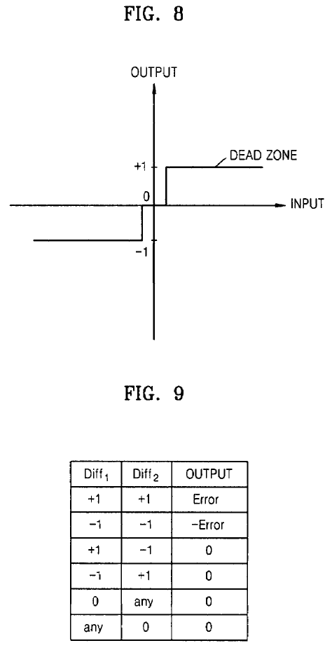

The dead zone code unit 705 redefines the output signal of the second subtractor 704 based on a dead zone, such as, for example, the dead zone illustrated in FIG. 8. The possible output signals of the dead zone code unit 705 are −1, +1, and 0. Accordingly, the output signal of the second subtractor 704 is converted into a dead zone code by the dead zone code unit 705. The dead zone code unit 705 transmits the output signal to the third delayer 706 and to the “Diff2” input port of the phase error calculator 707. Accordingly, the output signal of the dead zone code unit 705 can be defined as one of a plurality of differences between ideal input signals that are detected using N consecutive ideal input signal samples.

The addition of the dead zone code unit 705 simplifies the design of the phase error calculator 707. A truth table contained in the phase error calculator 707 may be structured as illustrated in FIG. 9. For example, when the output of the dead zone code unit 705 and the output of the third delayer 706 are all “+1,” the phase error calculator 707 outputs a signal that is input to its “Error” input port. The signal input to the “Error” input port is the difference between an input signal and an ideal input signal. When the dead zone width of the dead zone code unit 705 is controlled, the phase error signal generating unit 204 can optimize the robustness against noise and inter-symbol interference (ISI).

In general, channel characteristics change based on a variety of factors, such as a type of disc used and a time that the disc is used. Accordingly, it is beneficial to use an adaptive component to adjust a target channel or an ideal channel according to changes in the channel characteristics.

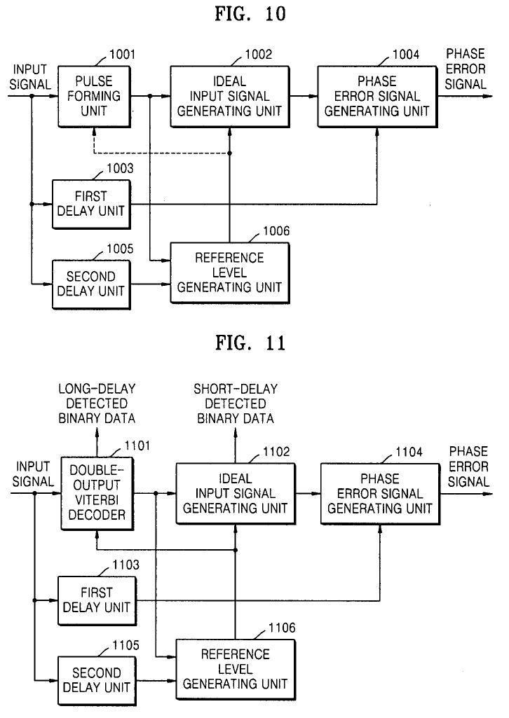

FIG. 10 is a block diagram of a phase detection apparatus according to another embodiment of the present invention. Referring to FIG. 10, the phase detection apparatus includes a pulse forming unit 1001, an ideal input signal generating unit 1002, a first delay unit 1003, a phase error signal generating unit 1004, a second delay unit 1005, and a reference signal generating unit 1006.

The first delay unit 1003 and the phase error generating unit 1004 are similar in structure and operation to the first delay unit 203 and the phase error generating unit 204 respectively illustrated in FIG. 2. The second delay unit 1005 delays an input signal by a delay time caused by the pulse forming unit 1001.

The reference level generating unit 1006 generates an adaptive reference level of a target channel based on the output signal of the pulse forming unit 1001 and the output signal of the second delay unit 1005. Specifically, the reference level generating unit 1006 generates a reference level, which is adaptive to a channel change, by comparing the output signal of the pulse forming unit 1001 to the output signal of the second delay unit 1005. By adapting to the channel change, the reference level generating unit 1006 adjusts the level of an ideal channel for signals that are input from the pulse forming unit 1001 and the second delay unit 1005. The adaptive level is used with the ideal input signal generating unit 1002. The adaptive level may also be used with the pulse forming unit 1001.

For example, the reference level generating unit 1006 classifies the output signals of the second delay unit 1005 into several groups based on binary data output from the pulse forming unit 1001, computes an average value of signals of each group, and generates the average value as a reference level. The average value of the signals may be generated using a filtering unit. It is understood that components other than a filtering unit may also be used to generate the average values of the output signals.

The use of the adaptive level makes it possible for the pulse forming unit 1001 to detect more accurate binary data. The ideal input signal generating unit 1002 can generate an ideal input signal with higher fidelity. Accordingly, the use of the reference level generating unit 1006 enhances the performance of the phase detection apparatus.

FIG. 11 is a block diagram of a phase detection apparatus according to another embodiment of the present invention. FIG. 11 illustrates an embodiment which avoids using two separate Viterbi decoders, such as a Viterbi decoder having a short delay to detect the phase of an input signal used with a Viterbi decoder having a long delay to reproduce a signal, to prevent the use of large scale hardware and large power consumption. To this end, the phase detection apparatus illustrated in FIG. 11 includes a double-output Viterbi decoder 1101, an ideal input signal generating unit 1102, a first delay unit 1103, a phase error signal generating unit 1104, a second delay unit 1105, and a reference level generating unit 1106.

The double-output Viterbi decoder 1101 includes two binary data outputs. The two binary data outputs output short-delay detected binary data to detect the phase of an input signal and long-delay detected binary data to reproduce a signal.

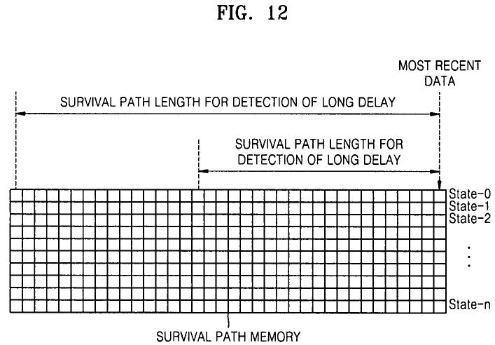

FIG. 12 is a diagram of a survival path memory of the double-output Viterbi decoder 1101 illustrating the way in which the double-output Viterbi decoder 1101 outputs the two types of binary data described above. Referring to FIG. 12, the survival path memory of the double-output Viterbi decoder 1101 has a predetermined size and stores data for maximum likelihood path selection. The data stored for maximum likelihood path selection generally depends on memory management schemes. In the survival path memory shown in FIG. 12, right-end cells store the most recent data and left-end cells store the earliest available data.

To detect a signal with a low bit rate, the length of the survival path memory must be sufficiently long to ensure a high probability of detection. Therefore, the total length of the survival path memory must be long enough for accurate signal detection. A portion of a survival path memory with a shorter delay is used in order to obtain short-delay detected binary data to detect the phase of an input signal. The survival path memory with a shorter delay is located on the right side of the previous survival path memory with a small delay, as shown in FIG. 12. For coarse and/or fine phase detection, the double-output Viterbi decoder 1101 may be shared during phase detection and signal reproduction.

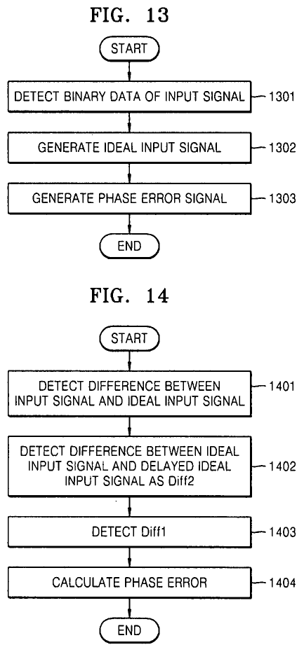

FIG. 13 is a flowchart illustrating a phase detecting method according to an embodiment of the present invention. Referring to FIG. 13, the method detects binary data of an input signal in operation 1301. The binary data may be detected as described in the pulse forming unit 201.

In operation 1302, an ideal input signal is generated based on the detected binary data. The ideal input signal may be generated as described above in reference to the description of the ideal input signal generation unit 203 shown in FIG. 2.

In operation 1303, a phase error signal is generated based on an input signal and an ideal input signal. The input signal used to generate the phase error signal may be an input signal that is delayed during the detection of the binary data and the generation of the ideal input signal.

FIG. 14 is a flowchart illustrating an example of the phase error signal generating operation 1303 illustrated in FIG. 13. Referring to FIG. 14, a difference between an input signal and an ideal input signal is detected in operation 1401. The input signal may be an input signal that is delayed during the detection of the binary data and the generation of the ideal input signal.

In operation 1402, a sample of the ideal input signal and a sample of the delayed ideal input signal are used to detect a difference “Diff2” between ideal input signals, as shown in FIG. 3. In operation 1403, the detected difference is delayed so that it is detected as “Diff1” as shown in FIG. 3. Operations 1402 and 1403 can be jointly defined as an operation of detecting a plurality of differences between ideal input signals using N consecutive ideal input signal samples.

In operation 1404, a phase error is calculated based on the differences detected in operations 1401, 1402 and 1403. This calculation may be performed as described in the phase error calculator 306 of FIG. 3.

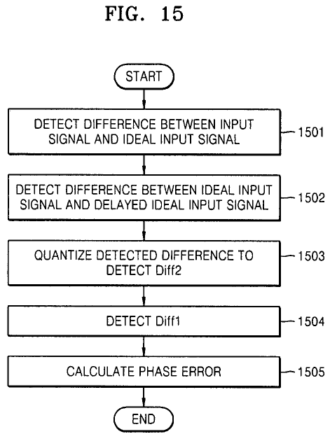

FIG. 15 is a flowchart illustrating another example of the phase error signal generating operation 1303 illustrated in FIG. 13. Referring to FIG. 15, a difference between an input signal and an ideal input signal is detected in operation 1501. The input signal may be an input signal that is delayed during the detection of the binary data and the generation of the ideal input signal.

In operation 1502, a sample of the ideal input signal and a sample of the delayed ideal input signal are used to detect a difference between ideal input signals. In operation 1503, the detected difference is quantized and the result is detected as “Diff2”, as shown in FIG. 3. The quantization may be performed as described above in reference to the description of the quantization unit 505 of FIG. 5.

In operation 1504, the quantized data in operation 1503 is delayed so that it is detected as “Diff1”, as shown in FIG. 3. In operation 1505, a phase error is calculated based on the differences detected in operations 1501, 1503 and 1504.

Instead of being quantized, the detected difference may instead be converted into a dead zone code in operation 1503. The conversion of the detected difference into the dead zone code may be performed as described above in reference to the description of the dead zone code unit 705 of FIG. 7. The result of the dead zone conversion in operation 1503 is detected as “Diff2” as shown in FIG. 3. In operation 1504, the dead zone data is delayed so that it is detected as “Diff1” as shown in FIG. 3.

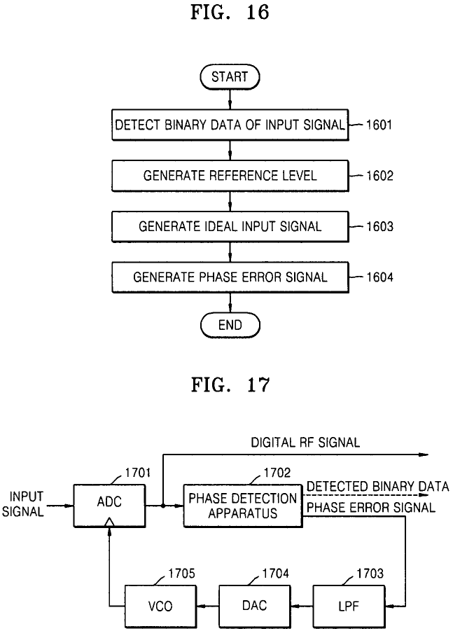

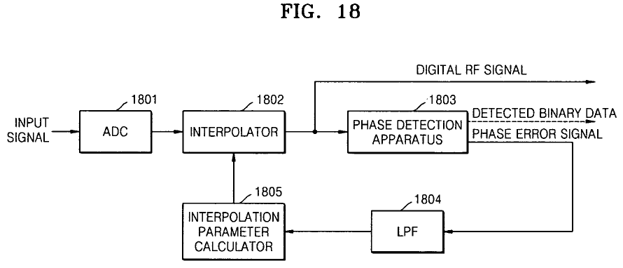

FIG. 16 is a flowchart illustrating a phase detecting method according to another embodiment of the present invention. Referring to FIG. 16, the method detects binary data of an input signal in operation 1601. In operation 1602, a reference level adaptive to a channel change is generated based on the detected binary data and the input signal. The reference level may be generated as described above in reference to the description of the reference level generating unit 1006 of FIG. 10.

In operation 1603, an ideal input signal is generated from the detected binary data based on the reference level. In operation 1604, a phase error signal is generated based on an input signal and an ideal input signal. The input signal may be an input signal that is delayed during the detection of the binary data and the generation of the ideal input signal.

Alternatively, operation 1601 may be performed using the double-output Viterbi decoder. In this case, the binary data detected in operation 1601 may include long-delay detected binary data and short-delay detected binary data.

FIG. 17 is a block diagram of a PLL circuit according to an embodiment of the present invention. Referring to FIG. 17, the PLL circuit includes an analog-to-digital converter (ADC) 1701, a phase detection apparatus 1702 according to an embodiment of the present invention, a low-pass filter (LPF) 1703, a digital-to-analog converter (DAC) 1704, and a voltage-controlled oscillator (VCO) 1705.

The ADC 1701 converts an analog input signal into a digital signal. The phase detection apparatus 1702 detects a phase error signal for the output signal of the ADC 1701. The phase detection apparatus 1702 may be one of the phase detection apparatuses illustrated in FIGS. 2, 10 and 11. Accordingly, the phase detection apparatus 1702 detects a phase error signal based on the output signal of the ADC 1701 and an ideal signal corresponding thereto.

The LPF 1703 low-pass filters the phase error signal output from the phase detection apparatus 1702. The DAC 1704 converts the output signal of the LPF 1703 into a second digital signal. The VCO 1705 generates a PLL clock signal using the output signal of the DAC 1704 and transmits the PLL clock signal to the ADC 1701. Accordingly, the ADC 1701 outputs a digital signal synchronized with the output signal of the VCO 1705.

When the PLL circuit is set to a closed loop, a phase error of a PLL clock signal is minimized to “0”. Specifically, when the PLL circuit is set to a closed loop, the PLL circuit generates a PLL clock signal synchronized with an analog input signal (or an RF signal). The PLL circuit can output a digital signal (or a digital RF signal) that is synchronized with the PLL clock signal transmitted from the ADC 1701 and binary data detected by the phase detection apparatus 1702. The binary data may be set to an optional output. By using the output of the detected binary data, the PLL circuit functions as a signal reproducing apparatus that is capable of reproducing an RF signal read from a disc.

FIG. 18 is a block diagram of a PLL circuit according to another embodiment of the present invention. Referring to FIG. 18, the PLL circuit includes an ADC 1801, an interpolator 1802, a phase detection apparatus 1803 according to an embodiment of the present invention, an LPF 1804, and an interpolation parameter calculator 1805.

The ADC 1801, the phase detection apparatus 1803, and the LPF 1804 are similar in structure and operation to the ADC 1701, the phase detection apparatus 1702, and the LPF 1703 respectively illustrated in FIG. 17.

Using the output signal of the ADC 1801 and an interpolation parameter transmitted from the interpolation parameter calculator 1805, the interpolator 1802 interpolates a digital input signal (or an RF signal), which is not synchronized with a PLL clock signal, with a digital input signal (or an RF signal) that is synchronized with the PLL clock signal. Accordingly, the interpolator 1802 outputs an input signal (or an RF signal) at an accurate sampling point.

The interpolation parameter calculator 1805 generates an interpolation parameter based on the output signal of the LPF 1804. The generated interpolation parameter is transmitted to the interpolator 1802. The interpolation parameter may include a parameter corresponding to the PLL clock signal.

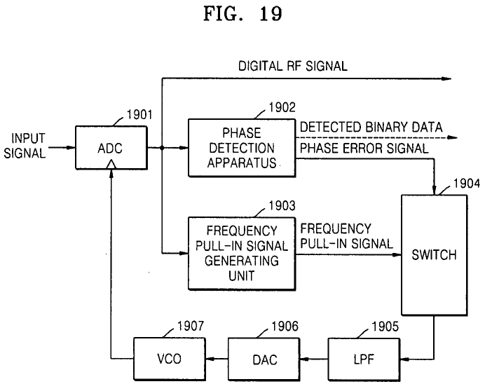

FIG. 19 is a block diagram of a PLL circuit according to another embodiment of the present invention, which uses a frequency pull-in mode because of the low speed of a phase locking process. Unlike the PLL circuit illustrated in FIG. 17, the PLL circuit illustrated in FIG. 19 further includes a frequency pull-in signal generating unit 1903 and a switch 1904.

The frequency pull-in signal generating unit 1903 receives the output signal of an ADC 1901 and generates a frequency pull-in signal. The frequency pull-in signal generating unit 1903 may be implemented using various methods. One well-known method which may be used to implement the frequency pull-in signal generating unit 1903 is to count the longest run-length sample of an RF signal reproduced from a disc. This well-known method calculates a frequency pull-in signal based on the principle that the non return to zero (NRZ) code of an optical disc always has the longest run length. A difference between the actual count result and an ideal value may therefore be used as the frequency pull-in signal.

Another well-known method is to calculate the run-length distribution of an RF signal. This other well-known method calculates a frequency pull-in signal based on the principle that a change in the run-length distribution is reflected in the fluctuation of a PLL clock frequency. Some signals related to distribution conversion may therefore be used as the frequency pull-in signal.

The switch 1904 selects and outputs one of phase error information and a frequency error signal to an LPF 1905. The switch 1904 may be set to alternate between a frequency pull-in mode and a phase locking mode. If a frequency error of a PLL clock signal is large, the frequency pull-in signal generating unit 1903 generates a frequency pull-in signal that is monotonically related to the frequency error of the PLL clock signal. If the absolute value of the frequency pull-in signal is greater than a predetermined threshold, the switch 1904 is set to a frequency pull-in mode in order to perform a PLL operation. In the frequency pull-in mode, the switch 1904 transmits the output signal of the frequency pull-in signal generating unit 1903 to the LPF 1905. At this point, a phase error signal transmitted from the phase detection apparatus 1902 is disregarded. Accordingly, the PLL circuit can rapidly minimize a frequency error in the frequency pull-in mode.

If the absolute value of the frequency pull-in signal is smaller than the predetermined threshold, the switch 1904 switches the PLL operation into a phase locking mode. In the phase locking mode, the phase error signal output from the phase detection apparatus 1902 is transmitted to the LPF 1905. At this point, an output signal from the frequency pull-in signal generating unit 1903 is disregarded. Accordingly, the PLL circuit can minimize a clock phase error in the phase locking mode.

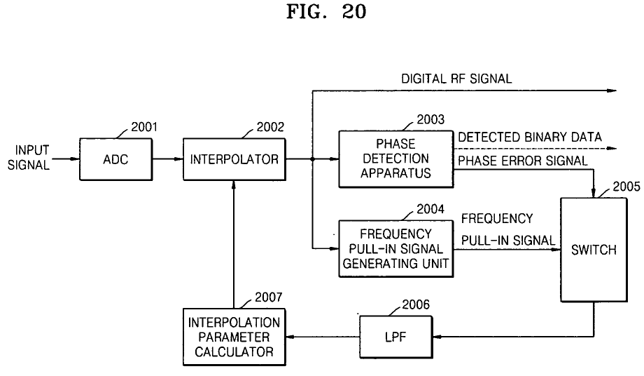

FIG. 20 is a block diagram of a PLL circuit according to another embodiment of the present invention. When compared to the PLL circuit illustrated in FIG. 19, the PLL circuit illustrated in FIG. 20 further includes an interpolator 2002 and an interpolation parameter calculator 2007, while excluding the DAC 1906 and the VCO 1907. The interpolator 2002 and the interpolation parameter calculator 2007 are similar in structure and operation to the interpolator 1802 and the interpolation parameter calculator 1805 respectively shown in FIG. 18. It can be appreciated that other components, such as a filter, a DC canceller, and a limit equalizer, may be added in various combinations to the above-described phase detection apparatuses.

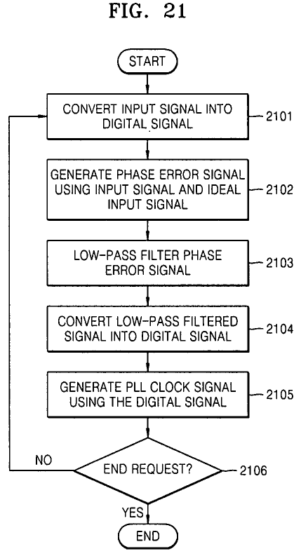

FIG. 21 is a flowchart illustrating a PLL controlling method according to an embodiment of the present invention. Referring to FIG. 21, an input signal is converted into a digital signal in operation 2101. In operation 2102, the digitized input signal and an ideal input signal corresponding to the input signal are used to generate a phase error signal. The phase error signal may be generated as described above with reference to FIGS. 13, 14, 15 and 16.

In operation 2103, the generated phase error signal is low-pass filtered. In operation 2104, the low-pass filtered phase error signal is converted into a digital signal. In operation 2105, the digital signal obtained in operation 2104 is used to generate a PLL clock signal. In operation 2106, it is determined if a request is made to end the process. If so, the process is ended; if not, the process returns to operation 2101.

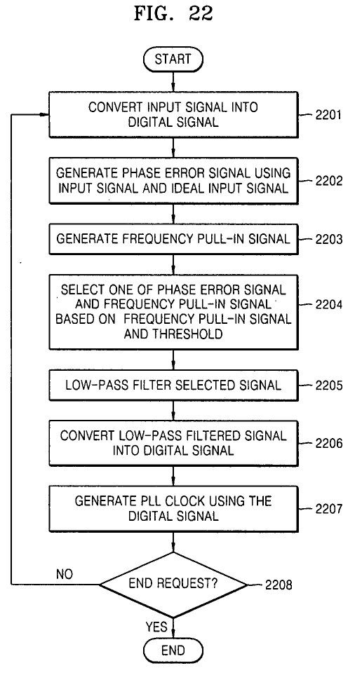

FIG. 22 is a flowchart illustrating a PLL controlling method according to another embodiment of the present invention. Referring to FIG. 22, an input signal is converted into a digital signal in operation 2201. In operation 2202, the digitized input signal and an ideal input signal corresponding to the input signal are used to generate a phase error signal. A frequency pull-in signal of the digitized input signal is generated in operation 2203. The frequency pull-in signal may be generated in the same way that the frequency pull-in signal generating unit 1903 of FIG. 19 generates a frequency pull-in signal.

In operation 2204, one of the phase error signal and the frequency pull-in signal is selected by comparing the frequency pull-in signal and a predetermined threshold. This selection may be performed in the same way that the switch 1904 of FIG. 19 performs a selection.

In operation 2205, the selected signal is low-pass filtered. In operation 2206, the low-pass filtered signal is converted into a digital signal. In operation 2207, the digital signal obtained in operation 2206 is used to generate a PLL clock signal. In operation 2208, it is determined if a request is made to end the process. If so, the process is ended; if not, the process returns to operation 2201.

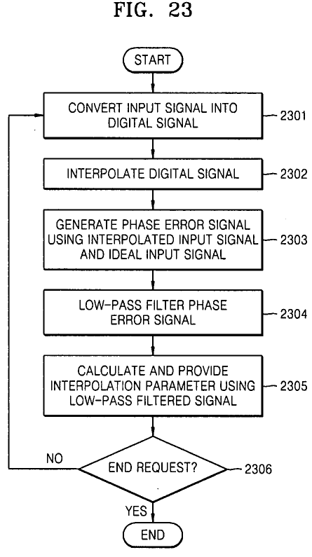

FIG. 23 is a flowchart illustrating a PLL controlling method according to still another embodiment of the present invention. Referring to FIG. 23, an input signal is converted into a digital signal in operation 2301. In operation 2302, the digitized input signal is interpolated based on an interpolation parameter. This interpolation may be performed in the same way that the interpolator 1802 of FIG. 18 performs an interpolation.

In operation 2303, the interpolated input signal and a corresponding ideal input signal are used to generate a phase error signal. In operation 2304, the generated phase error signal is low-pass filtered. In operation 2305, the low-pass filtered signal is used to calculate an interpolation parameter and the interpolation parameter is transmitted for an interpolation process. The interpolation parameter may be calculated in the same way that the interpolation parameter calculator 1805 illustrated in FIG. 18 calculates an interpolation parameter.

In operation 2306, it is determined if a request is made to end the process. If so, the process is ended; if not, the process returns to operation 2301.

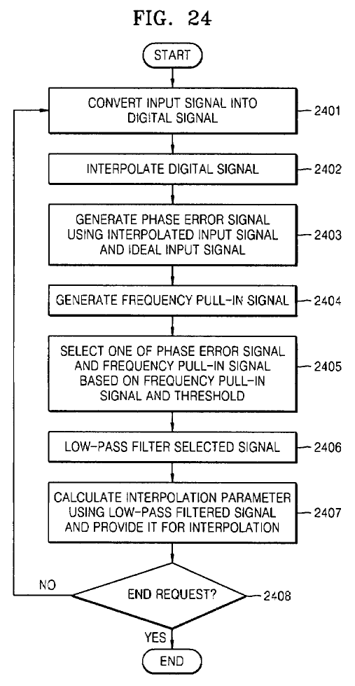

FIG. 24 is a flowchart illustrating a PLL controlling method according to another embodiment of the present invention. Referring to FIG. 24, an input signal is converted into a digital signal in operation 2401. In operation 2402, the digitized input signal is interpolated based on an interpolation parameter. This interpolation may be performed in the same way that the interpolator 1802 of FIG. 18 performs an interpolation.

In operation 2403, a phase error signal is generated using the interpolated input signal and a corresponding ideal input signal. A frequency pull-in signal of the interpolated signal is generated in operation 2404. The frequency pull-in signal may be generated in the same way that a frequency pull-in signal is generated by the frequency pull-in signal generating unit 1903 of FIG. 19. In operation 2405, the frequency pull-in signal is compared to a predetermined threshold to select one of the phase error signal and the frequency pull-in signal. This selection may be performed in the same way that the switch 1904 performs a selection, as described with reference to FIG. 19.

In operation 2406, the selected signal is low-pass filtered. In operation 2407, the low-pass filtered signal is used to calculate an interpolation parameter and the interpolation parameter is transmitted for an interpolation process. The interpolation parameter may be calculated in the same way that the interpolation parameter calculator 1805 of FIG. 18 calculates an interpolation parameter.

In operation 2408, it is determined if a request is made to end the process. If so, the process is ended; if not, the process returns to operation 2401.

As described above, a real input signal (or an RF signal) is compared with a corresponding ideal input signal (or an ideal RF signal) in order to detect a phase error, thereby making it possible to reproduce a stable signal with anti-noise and anti ISI characteristics.

In addition, a component for detecting binary data of an input signal is shared during the detection of a phase, the operation of the PLL circuit and the reproduction of a signal, thereby making it possible to reduce the scale and cost of the hardware used to implement the PLL circuit, and the power consumption of the system.

The methods according to aspects of the present invention can also be embodied as computer-readable codes on a computer-readable recording medium. The computer-readable recording medium is any data storage device that can store data which can be thereafter read by a computer system. Examples of the computer-readable recording medium include read-only memory (ROM), random-access memory (RAM), CD-ROMs, magnetic tapes, floppy disks, optical data storage devices, and a computer signal embodied in a carrier wave comprising a compression source code segment and an encryption source code segment (such as data transmission through the Internet). The computer-readable recording medium can also be distributed over network-coupled computer systems so that the computer-readable code is stored and executed in a distributed fashion.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. An apparatus to detect the phase of an input signal, the apparatus comprising:
a pulse forming unit to detect and output binary data of the input signal;
an ideal input signal generating unit to generate an ideal input signal based on the detected binary data; and
a phase error signal generating unit to generate a phase error signal based on the input signal and the ideal input signal.

2. The apparatus of claim 1, further comprising a reference level generating unit which compares the input signal with the binary data output by the pulse forming unit in order to generate a reference level adaptive to a channel change.

3. The apparatus of claim 2, wherein the reference level generating unit transmits the generated reference level to the pulse forming unit, and the pulse forming unit detects the binary data based on the generated reference level.

4. The apparatus of claim 3, further comprising:
a first delay unit to delay the input signal during operations of the pulse forming unit and the ideal input signal generating unit and to transmit the delayed input signal as the input signal used by the phase error signal generating unit to generate the phase error signal; and
a second delay unit to delay the input signal during the operation of the pulse forming unit and to transmit the delayed input signal as the input signal which the reference level generating unit compares to the output signal of the pulse forming unit.

5. The apparatus of claim 2, further comprising:
a first delay unit to delay the input signal during operations of the pulse forming unit and the ideal input signal generating unit and to transmit the delayed input signal as the input signal used by the phase error signal generating unit to generate the phase error signal; and
a second delay unit to delay the input signal during the operation of the pulse forming unit and to transmit the delayed input signal as the input signal which the reference level generating unit compares to the binary data output by the pulse forming unit.

6. The apparatus of claim 1, further comprising:
a first delay unit to delay the input signal during operations of the pulse forming unit and the ideal input signal generating unit and to transmit the delayed input signal as the input signal used by the phase error signal generating unit to generate the phase error signal.

7. The apparatus of claim 1, wherein the phase error signal generating unit comprises:
a first difference detector to detect and output a difference between the input signal and the ideal input signal;
a second difference detector to detect a plurality of differences between a plurality of other ideal input signals using N consecutive ideal input signal samples output from the ideal input signal generating unit; and
a phase error calculator to calculate a phase error based on the difference detected by the first difference detector and the plurality of differences detected by the second difference detector in order to generate the phase error signal,
wherein the difference detected by the first difference detector is a phase error.

8. The apparatus of claim 7, wherein the phase error signal generating unit further comprises a first delayer to delay the difference output by the first difference detector.

9. The apparatus of claim 8, wherein the second difference detector comprises:
a second delayer to delay and output the ideal input signal sample;
a detector to detect and output a difference between the ideal input signal sample and the ideal input signal sample output by the second delayer as one of the plurality of differences; and
a third delayer to delay the difference output by the detector and to output the delayed difference as another one of the plurality of differences.

10. The apparatus of claim 9, wherein the second difference detector further comprises a quantization unit to quantize the difference output by the detector, and to output the quantized difference to the third delayer and the phase error calculator as one of the plurality of differences.

11. The apparatus of claim 9, wherein the second difference detector further comprises a dead zone code unit to convert the difference output by the detector into a dead zone code and to output the dead zone code to the third delayer and the phase error calculator as one of the plurality of differences.

12. The apparatus of claim 2, wherein the binary data of the input signal comprises long-delay detected binary data and short-delay detected binary data.

13. The apparatus of claim 12, wherein the pulse forming unit comprises a double-output Viterbi decoder to output the long-delay detected binary data for signal reproduction and the short-delay detected binary data for phase detection.

14. The apparatus of claim 3, wherein the pulse forming unit comprises a double-output Viterbi decoder to output the detected binary data which is delayed for a long time to reproduce a signal and to output the detected binary data which is delayed for a short time to detect a phase.

15. The apparatus of claim 1, wherein the ideal input signal generating unit comprises a linear channel whose output is expressed by:
$$PR ( {I}_{1} , {I}_{2} , {I}_{3} , … , {I}_{n} ) = {\sum }_{j = 1}^{n} {I}_{j} \cdot X ( k - j )$$
where Iⱼ denotes a coefficient of the linear channel and X(k) denotes the detected binary data with a value of 1 or −1 that is input at a point of time k.

16. The apparatus of claim 1, wherein the ideal input signal generating unit comprises an arbitrary channel whose output is expressed by:
PRₙ=F(X(k),X(k−1),X(k−2), . . . ,X(k−n+1))
where n denotes a finite window length, X(k) denotes the detected binary data with a value of 1 or −1 that is input at a point of time k, and F( . . . ) is a representation of PRₙ as a function of X(k), X(k−1), . . . , X(k−n+1).

17. The apparatus of claim 16, wherein the arbitrary channel is implemented as a memory structure.

18. A method of detecting a phase of an input signal, the method comprising:
detecting binary data of the input signal;
generating an ideal input signal based on the detected binary data; and
generating a phase error signal based on the binary data and the ideal input signal.

19. The method of claim 18, wherein the generating of the phase error signal comprises:
detecting a difference between the input signal and the ideal input signal;
detecting a plurality of differences between a plurality of other ideal input signals using N consecutive ideal input signal samples; and
calculating a phase error based on the detected difference and the detected plurality of differences to generate the phase error signal.

20. The method of claim 19, wherein the detecting of the plurality of differences between the plurality of other ideal input signals comprises quantizing one of the plurality of differences and detecting the plurality of differences used to generate the phase error signal based on the quantization results.

21. The method of claim 19, wherein the detecting of the plurality of differences between the plurality of other ideal input signals comprises converting one of the plurality of differences into a dead zone code and detecting a plurality of differences used to generate the phase error signal based on results of the conversion into the dead zone code.

22. The method of claim 18, further comprising generating a reference level adaptive to a channel change based on the input signal and the detected binary data, wherein the ideal input signal is generated based on the generated reference level.

23. The method of claim 18, wherein the binary data of the input signal comprises long-delay detected binary data and short-delay detected binary data.

24. A PLL (phase locked loop) circuit comprising:
an ADC (analog-to-digital converter) to convert an input signal into a digital signal and output the digital signal;
a phase detector to detect a phase error signal of the digital signal output by the ADC;
an LPF (low pass filter) to low-pass filter the detected phase error signal;
a DAC (digital-to-analog converter) to convert the low-pass filtered signal of the LPF into a second digital signal; and
a VCO (voltage-controlled oscillator) to generate a clock signal of the PLL using the second digital signal converted by the DAC,
wherein the phase detector detects the phase error signal based on the digital signal output by the ADC and an ideal input signal corresponding to the digital signal output by the ADC.

25. The PLL circuit of claim 24, wherein the digital signal output by the ADC is a digital signal synchronized with the clock signal.

26. The PLL circuit of claim 24, wherein the phase detector further outputs binary data of the digital signal output by the ADC.

27. The PLL circuit of claim 24, further comprising:
a frequency pull-in signal generating unit to generate a frequency pull-in signal based on the digital signal output by the ADC; and
a switch to select one of the phase error signal transmitted from the phase detector and the frequency pull-in signal transmitted from the frequency pull-in signal generating unit and to transmit the selected signal to the LPF,
wherein the LPF low-pass filters the selected signal instead of the phase error signal.

28. The PLL circuit of claim 27, wherein if an absolute value of the frequency pull-in signal is greater than a predetermined threshold, the switch is set to a frequency pull-in mode to select the frequency pull-in signal and transmit the selected frequency pull-in signal to the LPF, and if the absolute value of the frequency pull-in signal is not greater than the predetermined threshold, the switch is set to a phase locking mode to select the phase error signal and transmit the selected phase error signal to the LPF.

29. The PLL circuit of claim 24, wherein the phase detector comprises:
a pulse forming unit to detect binary data of the input signal;
an ideal input signal generating unit to generate the ideal input signal based on the detected binary data; and
a phase error signal generating unit to generate the phase error signal based on the input signal and the ideal input signal.

30. A PLL (phase locked loop) circuit comprising:
an ADC (analog-to-digital converter) to convert an input signal into a digital signal and output the digital signal;
an interpolator to interpolate the digital signal output by the ADC;
a phase detector to detect and output a phase error signal of the interpolated digital signal;
an LPF (low pass filter) to low-pass filter the detected phase error signal; and
an interpolation parameter calculator to calculate an interpolation parameter based on the low-pass filtered signal and to transmit the calculated interpolated parameter to the interpolator.

31. A method of controlling a phase locked loop (PLL) which receives an input signal, the method comprising:
generating a phase error signal using the input signal and an ideal input signal corresponding to the input signal;
low-pass filtering the phase error signal;
converting the low-pass filtered signal into a digital signal; and
generating a clock signal of the PLL using the digital signal.

32. A method of controlling a phase locked loop (PLL) which receives an input signal, the method comprising:
interpolating the input signal;
generating a phase error signal using the interpolated signal and an ideal input signal corresponding to the interpolated signal;
low-pass filtering the phase error signal; and
calculating an interpolation parameter using the low-pass filtered signal and using the interpolation parameter for the interpolating of the input signal.

33. A signal reproducing apparatus with a function of detecting a phase of an RF (radio frequency) signal read from a disc, the signal reproducing apparatus comprising:
a pulse forming unit to detect and output binary data of the RF signal;
an ideal input signal generating unit to generate an ideal input signal based on the detected binary data; and
a phase error signal generating unit to generate a phase error signal based on the input signal and the ideal input signal,
wherein the binary data is a reproduction signal.
